(19) United States
(12) Patent Application Publication
(10) Pub. No.: US 2013/0277801 A1
(43) Pub. Date: Oct. 24, 2013

(54) CHIP PACKAGE

(71) Applicant: MEDIATEK INC., Hsin-Chu (TW)

(72) Inventors: Nan-Cheng CHEN, Hsin-Chu City (TW); Tung-Hsien HSIEH, Zhubei City (TW)

(73) Assignee: MediaTek Inc., Hsin-Chu (TW)

(21) Appl. No.: 13/790,097

(22) Filed: Mar. 8, 2013

Related U.S. Application Data
(60) Provisional application No. 61/635,493, filed on Apr. 19, 2012.

(51) Int. Cl. H01L 23/522

(52) U.S. Cl. CPC H01L 23/5223
USPC 257/532

(57) ABSTRACT

According to an embodiment of the invention, a chip package is provided. The chip package includes: a lower chip package; an upper chip package disposed on an upper surface of the lower chip package; at least one conducting element disposed between the lower chip package and the upper chip package; and at least one decoupling capacitor disposed on the upper surface of the lower chip package, wherein the decoupling capacitor is not covered by the upper chip package, and the decoupling capacitor is electrically connected to a power line or a ground line in the lower chip package.

### CROSS REFERENCE TO RELATED APPLICATIONS

This Application claims the benefit of U.S. Provisional Application No. 61/635,493, filed on Apr. 19, 2012, the entirety of which is incorporated by reference herein.

### BACKGROUND OF THE INVENTION

1. Field of the Invention

The invention relates to a package, and in particular, relates to a chip package.

2. Description of the Related Art

A growing trend in semiconductor manufacturing, is for semiconductor manufacturers to adopt three-dimensional (3D) interconnects and packaging techniques for semiconductor devices. Three-dimensional interconnects have advantages such as size reduction, reduced interconnect length, and integration of devices with different functionalities, all within a respective package.

A chip package not only provides protection for the chips from environmental contaminants, but also provides a connection interface for chips packaged therein. Stacked packaging schemes, such as package-on-package (POP) packaging, have become increasingly popular. The stacking of different semiconductor packages using stacked packages typically reduces the required footprint size for a semiconductor package in an electronic product. Furthermore, stacked packages can provide a modular solution for constructing electronic devices by permitting different combinations of stacked semiconductor packages using only a few semiconductor package footprints.

Recently, power delivery network (PDN) issues in chip design have become more and more severe due to the implementation of high-speed CPUs, GPUs, and/or DRAMs. As the demand for faster and smaller electronic products increase, a PoP package for high-speed CPUs, GPUs, and/or DRAMs is desired.

### BRIEF SUMMARY OF THE INVENTION

According to an embodiment of the invention, a chip package is provided. The chip package includes: a lower chip package; an upper chip package disposed on an upper surface of the lower chip package; at least one conducting element disposed between the lower chip package and the upper chip package; and at least one decoupling capacitor disposed on the upper surface of the lower chip package, wherein the decoupling capacitor is not covered by the upper chip package, and the decoupling capacitor is electrically connected to a power line or a ground line in the lower chip package.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a cross-sectional view showing a chip package according to an embodiment of the present invention;

FIG. 2 is a top view showing a lower portion of a chip package according to an embodiment of the present invention;

FIG. 3 is a cross-sectional view showing a chip package according to an embodiment of the present invention;

FIG. 4 is a cross-sectional view showing a chip package according to an embodiment of the present invention;

FIG. 5 is a cross-sectional view showing a chip package according to an embodiment of the present invention;

FIG. 6 is a cross-sectional view showing a chip package according to an embodiment of the present invention;

FIG. 7A is a cross-sectional view showing a chip package according to an embodiment of the present invention; and

FIG. 7B is a perspective view showing one of the decoupling capacitors shown in FIG. 7A.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The manufacturing method and method for use of the embodiment of the invention are illustrated in detail as follows. It is understood, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

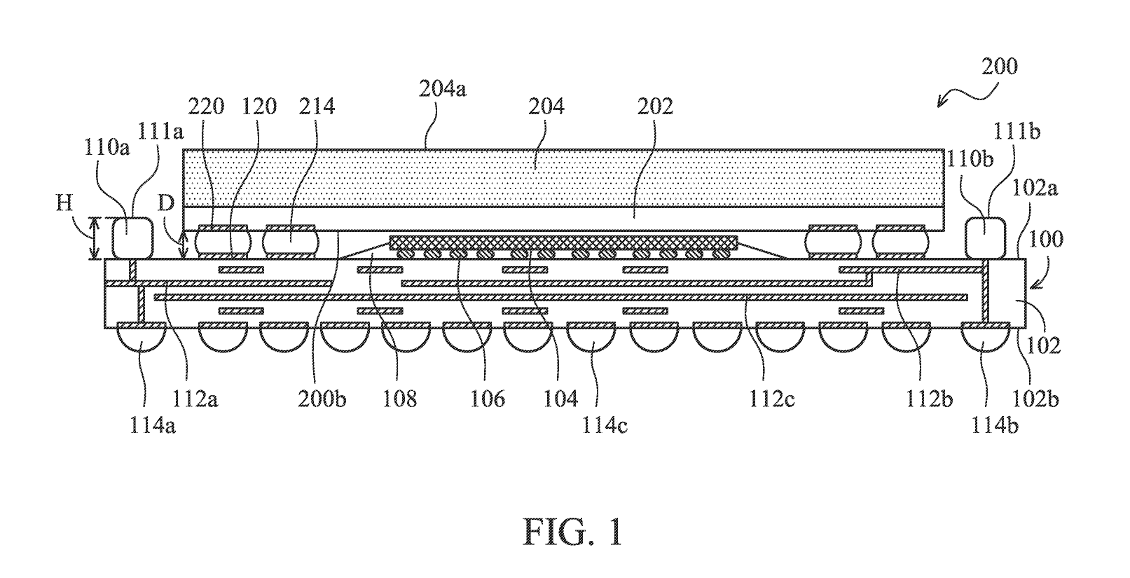

FIG. 1 is a cross-sectional view showing a chip package according to an embodiment of the present invention. As shown in FIG. 1, a chip package having a package-on package (PoP) structure is provided. The chip package includes a lower chip package 100 and an upper chip package 200 stacked thereon. In one embodiment, the lower chip package 100 and the upper chip package 200 are electrically communicated with each other. For example, electrical signals may be transmitted between the chip packages 100 and 200 through at least one conducting element 214 disposed therebetween. The conducting element 214 may include (but is not limited to) a solder ball or other suitable conducting structure. Although only two chip packages 100 and 200 are stacked in the embodiment shown in FIG. 1, embodiments of the invention are not limited thereto. In another embodiment, three or more chip packages may be stacked to form a chip package having the package-on-package (PoP) structure. In one embodiment, the upper chip package 200 has an area which is smaller than that of the lower chip package 100. In one embodiment, the lower chip package 100 may be extended to have a larger area such that the lower chip package 100 has a region not covered by the upper chip package 200.

In one embodiment, the upper chip package 200 may include a chip 204, an insulating layer 202, and a plurality of contact pads 220. The chip 204 has a plurality of electronic elements, wherein each of the electronic elements is electrically connected to at least one of the contact pads 220 through wire layers (not shown) formed in the insulating layer 202. The conducting element 214 may be disposed on the contact pad 220 for transmitting electrical signals to the lower chip package 100.

In one embodiment, the lower chip package 100 may include a chip 104 disposed on an upper surface 102a of a substrate 102. The substrate 102 may be an insulating substrate having a plurality of wire layers such as wire layers 112a, 112b, and 112c formed therein. Alternatively, the substrate 102 may be a semiconductor substrate having a plurality of wire layers formed therein. In this case, insulating layers may be formed between the wire layers and the semiconductor substrate to prevent short circuiting from occurring between the wire layers. In one embodiment, the chip 104 is different from the chip 204 and has functionality different from that of the chip 204. The chip 104 may have an area different from that of the chip 204. For example, the chip 204 may have an area which is larger than that of the chip 104. Alternatively, the chip 204 may have an area which is smaller than or equal to that of the chip 104. In another embodiment, the chip 104 and the chip 204 may have similar functionality.

A plurality of contact pads 120 may be formed on the upper surface 102a of the chip package 100. Some of the contact pads may be electrically connected to the electronic elements in the chip 104 via the wire layers formed in the substrate 102 and conducting terminals 106 formed on the bottom surface of the chip 104. Thus, the chip 104 and the chip 204 may be electrically communicated with each other via the conducting element 214 electrically connecting the contact pads 220 and 120. In one embodiment, an underfill layer 108 may be optionally formed between the chip 104 and the upper surface 102a of the substrate 102 to surround and protect the conducting terminals 106. A plurality of conducting bumps including, for example, solder balls 114a, 114b, and 114c may be optionally formed on a bottom surface 102b of the substrate 102. Some of the conducting bumps such as the solder ball 114c may be electrically connected to the chip 104 and/or the chip 204 via the wire layers formed in the substrate 102.

As shown in FIG. 1, at least one decoupling capacitor may be disposed on the upper surface 102a of the substrate 102. The decoupling capacitor may be electrically connected to the chip 104 and/or the chip 204. In one embodiment, a decoupling capacitor 110a may be formed on a conducting layer or a pad (not shown) formed on the upper surface 102a of the lower chip package 100. There may be no solder ball disposed between the decoupling capacitor 110a and the lower chip package 100. In one embodiment, at least one of the solder balls disposed on the bottom surface 102b of the lower chip package 100 such as the solder ball 114a may be electrically connected to the decoupling capacitor 110a.

In one embodiment, the decoupling capacitor 110a has a top surface 111a. In one embodiment, the top surface 111a is lower than a top surface 204a of the upper chip package 200. In one embodiment, the upper surface 102a of the lower chip package 100 is separated from a bottom surface 200b of the upper chip package 200 by a distance D. In one embodiment, the decoupling capacitor 110a has a height H larger than or equal to the distance D between the upper chip package 200 and the lower chip package 100. That is, the distance D between the upper chip package 200 and the lower chip package 100 is not larger than the height H of the decoupling capacitor 110a. In one embodiment, the decoupling capacitor 110a is electrically connected to the wire layer 112a. In one embodiment, the wire layer 112a is a power line. The power line (112a) may be electrically connected to a dynamic random access memory (DRAM) which may be disposed on or in the lower chip package 100 and/or the upper chip package 200. Alternatively, the power line (112a) may be electrically connected to a central processing unit (CPU) or a graphic processing unit (GPU) which may be disposed on or in the lower chip package 100 and/or the upper chip package 200. In another embodiment, the wire layer 112a is a ground line.

As shown in FIG. 1, in one embodiment, the decoupling capacitor 110a is not covered by the upper chip package 200. In one embodiment, a projection of the upper chip package 200 on the upper surface 102a of the lower chip package 100 does not overlap with a projection of the decoupling capacitor 110a on the upper surface 102a of the lower chip package 100. In one embodiment, the lower chip package 100 has an area which is larger than that of the upper chip package 200. The decoupling capacitor 110a may be disposed on the region of the upper surface 102a not covered by the upper chip package 200. Thus, the height H and the kinds of the decoupling capacitor 110a are not limited by the distance D between the upper chip package 200 and the lower chip package 100. The chip design for power delivery network (PDN) issues is easier.

In one embodiment, at least one decoupling capacitor other than the decoupling capacitor 110a may be optionally disposed on the upper surface 102a of the lower chip package 100. For example, a decoupling capacitor 110b is disposed on the upper surface 102a of the lower chip package 100. The decoupling capacitor 110b may be electrically connected to the chip 104 and/or the chip 204. Similarly, the decoupling capacitor 110b may not be covered by the upper chip package 200. Thus, the height and the kinds of the decoupling capacitor 110b are not limited by the distance D between the upper chip package 200 and the lower chip package 100. A top surface 111b of the decoupling capacitor 110b may be lower than the top surface 204a of the upper chip package 200. In one embodiment, the heights of the decoupling capacitor 110a and the decoupling capacitor 110b may be substantially the same. The heights of the decoupling capacitors 110a and 110b may be larger than the distance D between the bottom surface 200b of upper chip package 200 and upper surface 102a of the lower chip package 100. In one embodiment, the decoupling capacitor 110b may have a height which is different from that of the decoupling capacitor 110a.

In one embodiment, the decoupling capacitor 110b is electrically connected to the wire layer 112b. The wire layer 112b may be a power line. The power line (112b) may be electrically connected to a dynamic random access memory (DRAM). Alternatively, the power line (112b) may be electrically connected to a central processing unit (CPU) or a graphic processing unit (GPU). In another embodiment, the wire layer 112b is a ground line.

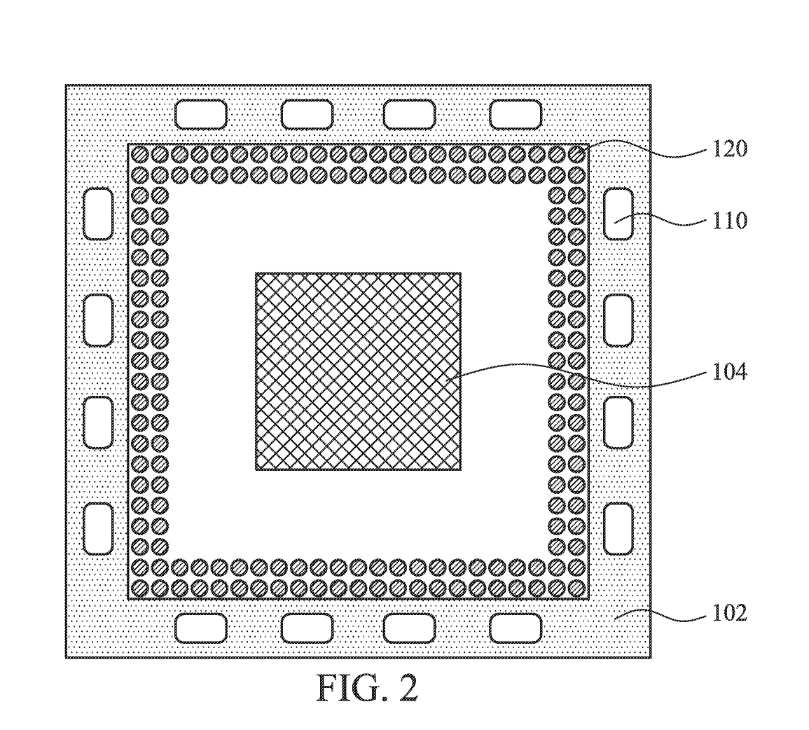

FIG. 2 is a top view showing a lower portion of a chip package according to an embodiment of the present invention, wherein same or similar reference numbers are used to designate same or similar elements. As shown in FIG. 2, top views of the lower chip package 100 and a plurality of decoupling capacitors 110 disposed on the substrate 102 are illustrated. The chip 104 may have a plurality of elements electrically connected to the contact pads 120 surrounding the chip 104. The contact pads 120 are used to carry the conducting elements 214 (see FIG. 1) such that the chips 104 and 204 may be electrically communicated with each other. The decoupling capacitors 110 may surround the conducting elements 214 and the chip 104 and may be electrically connected to the chip 104 and/or the chip 204 via the wire layers in the lower chip package 100, the contact pads 120, and the conducting elements 214.

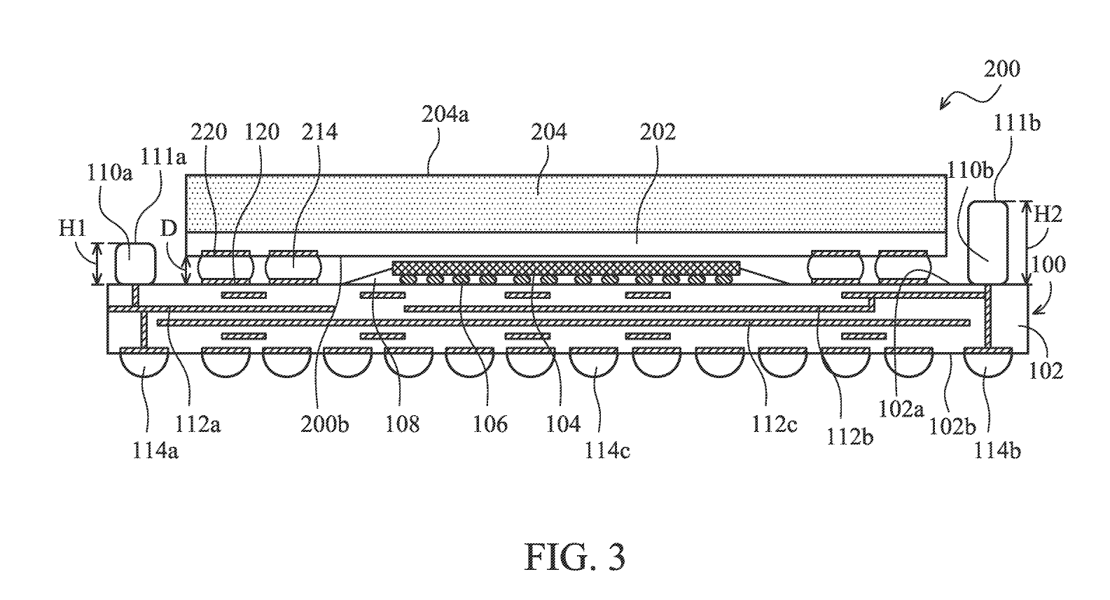

FIG. 3 is a cross-sectional view showing a chip package according to an embodiment of the present invention, wherein same or similar reference numbers are used to designate same or similar elements. FIG. 3 shows a chip package having a structure similar to the structure shown in FIG. 1. The main difference therebetween is that the decoupling capacitor 110b has a height H2 which is larger than the height H1 of the decoupling capacitor 110a. In this embodiment, the top surface 111b of the decoupling capacitor 110b is lower than the top surface 204a of the upper chip package 200.

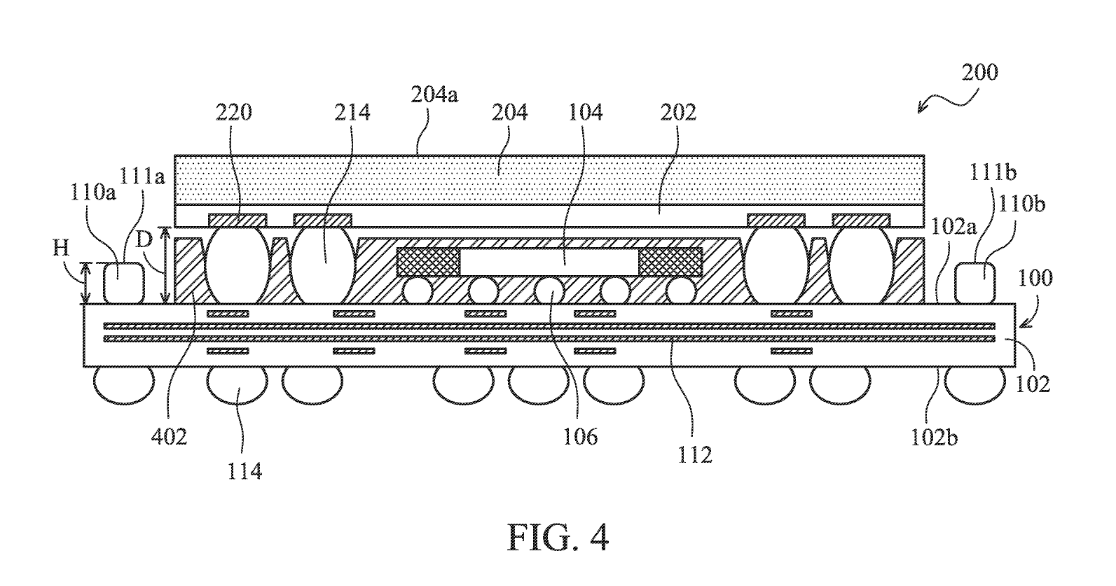

FIG. 4 is a cross-sectional view showing a chip package according to an embodiment of the present invention, wherein same or similar reference numbers are used to designate same or similar elements. In this embodiment, a molding compound 402 may be optionally formed between the lower chip package 100 and the upper chip package 200. The molding compound 402 may completely cover the chip 104 of the lower chip package 100. In one embodiment, the molding compound 402 may partially cover the conducting element 214 such that a portion of the conducting element 214 may protrude from the molding compound 402. In this embodiment, the height H of the decoupling capacitor 110a may be smaller than the distance D between the lower chip package 100 and the upper chip package 200.

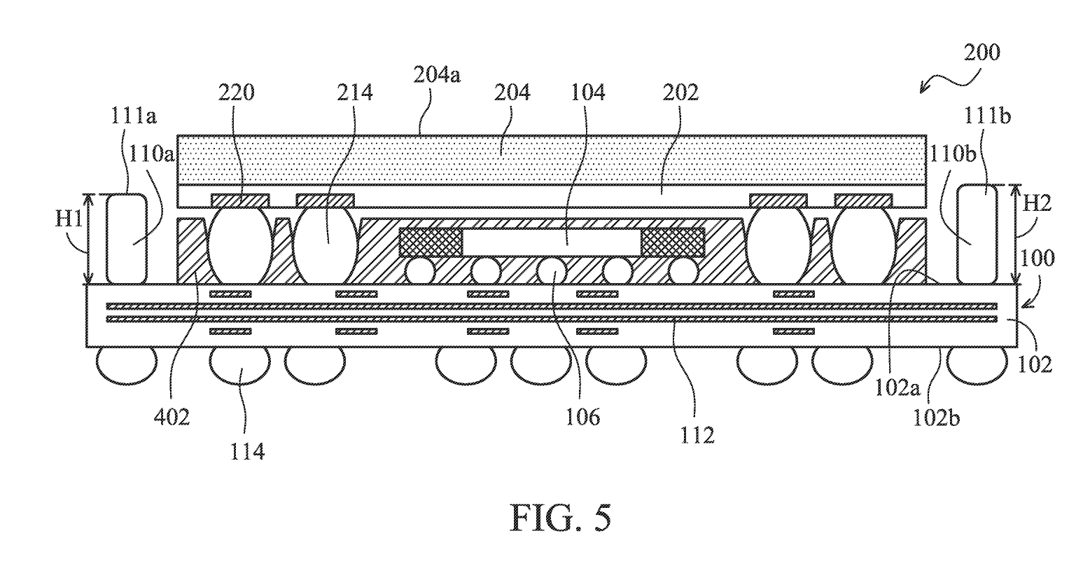

FIG. 5 is a cross-sectional view showing a chip package according to an embodiment of the present invention, wherein same or similar reference numbers are used to designate same or similar elements. FIG. 5 shows a chip package having a structure similar to the structure shown in FIG. 4. The main difference therebetween is that both the decoupling capacitors 110a and 110b have heights (H1 and H2) larger than the distance D between the upper chip package 200 and the lower chip package 100. In one embodiment, the height H2 of the decoupling capacitors 110b is different from the height H1 of the decoupling capacitor 110a. In this embodiment, both the top surfaces 111a and 111b of the decoupling capacitors 110a and 110b are lower than the top surface 204a of the upper chip package 200.

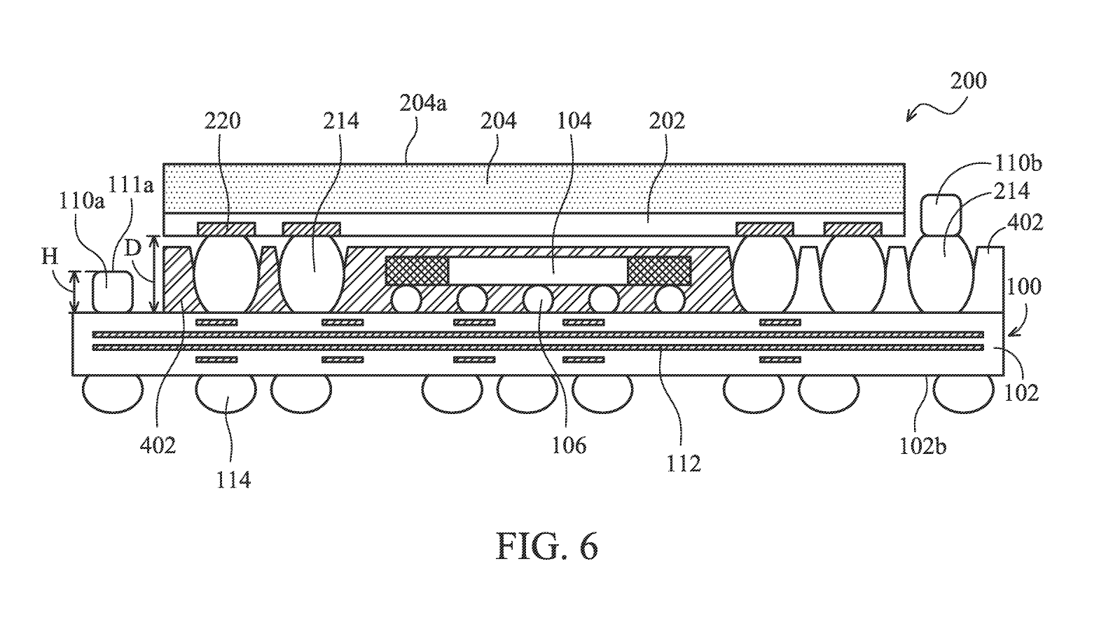

FIG. 6 is a cross-sectional view showing a chip package according to an embodiment of the present invention, wherein same or similar reference numbers are used to designate same or similar elements. FIG. 6 shows a chip package having a structure similar to the structure shown in FIG. 4. In this embodiment, the decoupling capacitor 110b is disposed on one of the conducting elements 214 disposed on the lower chip package 100. A portion of the conducting element 214 may protrude from the molding compound 402 to electrically contact with the decoupling capacitor 110b. Both the decoupling capacitor 110b and the conducting element 214 thereunder are not covered by the upper chip package 200.

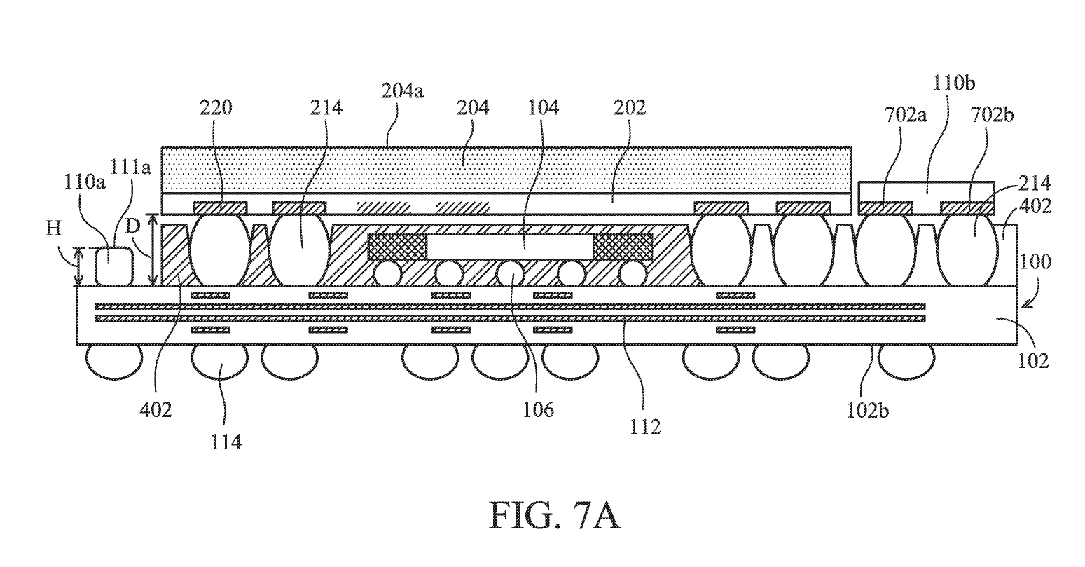

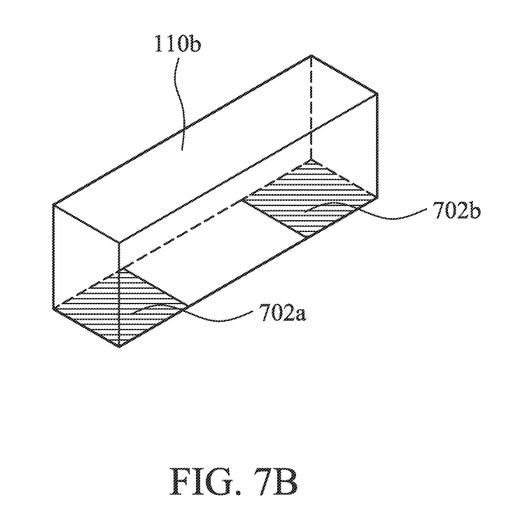

FIG. 7A is a cross-sectional view showing a chip package according to an embodiment of the present invention, and FIG. 7B is a perspective view showing the decoupling capacitor 110b shown in FIG. 7A, wherein same or similar reference numbers are used to designate same or similar elements. FIG. 7A shows a chip package having a structure similar to the structure shown in FIG. 6. In this embodiment, the decoupling capacitor 110b has at least two terminals 702a and 702b. The decoupling capacitor 110b may have a structure such as that shown in FIG. 7B. The two terminals 702a and 702b of the decoupling capacitor 110b may be disposed on two of the conducting elements 214 disposed on the lower chip package 100. Portions of the conducting elements 214 may protrude from the molding compound 402 to electrically contact with the terminals 702a and 702b of decoupling capacitor 110b, respectively.

In the embodiments of the invention, the decoupling capacitors are disposed on a region of the lower chip package not covered by the upper chip package such that the heights of the decoupling capacitors 110a are not limited by the distance between the upper chip package and the lower chip package. The chip design for power delivery network (PDN) in a PoP structure may be easier because of broader selection in the kinds and/or the sizes of the decoupling capacitors. A PoP package for high-speed CPUs, GPUs, and/or DRAMs is achieved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip package, comprising:
a lower chip package;
an upper chip package disposed on an upper surface of the lower chip package;
at least one conducting element disposed between the lower chip package and the upper chip package; and
at least one decoupling capacitor disposed on the upper surface of the lower chip package, wherein the decoupling capacitor is not covered by the upper chip package, and the decoupling capacitor is electrically connected to a power line or a ground line in the lower chip package.

2. The chip package as claimed in claim 1, wherein a top surface of the decoupling capacitor is lower than a top surface of the upper chip package.

3. The chip package as claimed in claim 1, wherein the upper surface of the lower chip package is separated from a bottom surface of the upper chip package by a distance, and the distance is not larger than a height of the decoupling capacitor.

4. The chip package as claimed in claim 1, wherein the power line is a power line electrically connected to a DRAM.

5. The chip package as claimed in claim 1, wherein the power line is a power line electrically connected to a CPU or a GPU.

6. The chip package as claimed in claim 1, further comprising a molding compound disposed between the lower chip package and the upper chip package.

7. The chip package as claimed in claim 6, wherein the molding compound completely covers a chip of the lower chip package.

8. The chip package as claimed in claim 6, wherein the molding compound covers the conducting element, and a portion of the conducting element protrudes from the molding compound.

9. The chip package as claimed in claim 1, further comprising at least a second decoupling capacitor disposed on the upper surface of the lower chip package, wherein the second decoupling capacitor is not covered by the upper chip package, and the decoupling capacitor is electrically connected to a power line or a ground line in the lower chip package.

10. The chip package as claimed in claim 9, wherein a top surface of the second decoupling capacitor is lower than a top surface of the upper chip package.

11. The chip package as claimed in claim 10, wherein the second decoupling capacitor has a height different from that of the decoupling capacitor.

12. The chip package as claimed in claim 11, wherein the height of the second decoupling capacitor is larger than a distance between the upper surface of the lower chip package and a bottom surface of the upper chip package.

13. The chip package as claimed in claim 1, further comprising a plurality of solder balls disposed on a bottom surface of the lower chip package, wherein at least one of the solder balls is electrically connected to the decoupling capacitor.

14. The chip package as claimed in claim 1, wherein the decoupling capacitor electrically contacts with a second conducting element disposed on the lower chip package.

15. The chip package as claimed in claim 1, wherein the upper chip package has an area smaller than that of the lower chip package.

16. The chip package as claimed in claim 1, wherein there is no solder ball disposed between the decoupling capacitor and the lower chip package.

17. The chip package as claimed in claim 1, wherein a projection of the upper chip package on the upper surface of the lower chip package does not overlap with a projection of the decoupling capacitor on the upper surface of the lower chip package.

18. The chip package as claimed in claim 1, wherein the at least one conducting element comprises a plurality of conducting elements, the at least one decoupling capacitor comprises a plurality of decoupling capacitors, and the decoupling capacitors surround the conducting elements.

19. The chip package as claimed in claim 1, wherein the decoupling capacitor has at least two terminals electrically contacting with two second conducting elements disposed on the lower chip package, respectively.

20. The chip package as claimed in claim 1, wherein the lower chip package comprises a first chip, the upper chip package comprises a second chip, and the first chip has an area different from that of the second chip.
